(19) United States
(12) Patent Application Publication
(10) Pub. No.: US 2026/0355839 A1
(43) Pub. Date: Nov. 12, 2026

(54) SOLDER MATERIAL, METHOD FOR PRODUCING SOLDER SHEET, AND METHOD FOR PRODUCING SEMICONDUCTOR DEVICE

(71) Applicant: Mitsubishi Electric Corporation, Tokyo (JP)

(72) Inventor: Koji YAMAZAKI, Tokyo (JP)

(73) Assignee: Mitsubishi Electric Corporation, Tokyo (JP)

(21) Appl. No.: 19/134,761

(22) PCT Filed: Feb. 21, 2023
(86) PCT No.: PCT/JP2023/006253

§ 371 Date: Jun. 2, 2025

(51) Int. Cl. B23K 1/00; H10W 72/00; H10W 72/30

(52) U.S. Cl. CPC B23K 1/0016; H10W 72/01357; H10W 72/07332; H10W 72/07336; H10W 72/352

(57) ABSTRACT

A solder material that enables bonding at 250 °C or lower and has a heat resistance of 180 °C or higher. The solder material contains Sn, Zn, and Al as main components. The solder material has two endothermic peaks in differential scanning calorimetry, and a first alloy phase having an endothermic peak in a range of 190 °C or higher and lower than 230 °C and a second alloy phase having an endothermic peak in a range of 240 °C or higher and lower than 380 °C coexist.

### TECHNICAL FIELD

The present disclosure relates to a solder material, a method for producing a solder sheet, and a method for producing a semiconductor device.

### BACKGROUND ART

In recent years, the reliability of semiconductor devices is becoming more and more demanded, and especially, semiconductor devices using wide bandgap semiconductor elements such as SiC and GaN having a higher withstand voltage and lower loss properties than conventional Si semiconductor elements have been developed. The operation temperature of a conventional semiconductor device using Si is approximately 125 °C whereas the operation temperature of a semiconductor device using SiC, GaN, or the like is 175 °C or higher. Therefore, solder materials for bonding a semiconductor element to a bonding target member are required to have a higher heat resistance. In addition, Pb-free solder materials not including Pb, which is an environmental regulation target substance, have been increasingly adopted in order to reduce environmental loads.

A solder material having a composition of Sn-3Ag-0.5Cu (the numerical values represent the weight percentages; hereinafter referred to as SAC305), which is a representative composition of a conventional Pb-free solder material, has a melting point of 220 °C. Accordingly, the SAC 305 is softened when reaching 175 °C or higher, thus making it impossible to obtain sufficient bonding strength. Examples of alternatives of the SAC305 include a sintering Ag bonding material using a nano silver particle, albeit not a solder material. However, since the nano silver particle is costly and the sintering Ag bonding material requires high pressure when performing pressure-bonding, disadvantages in terms of the cost and the bonding process are great.

As a method for achieving a higher heat resistance of a Sn-based solder material, a Zn-based solder material in which a part of Sn serving as a main component is substituted with Zn has been developed. For example, a solder material in which, with respect to the total of 100 wt %, Sn accounts for 10 wt % to 70 wt %, and Al accounts for 2 wt % to 10 wt %, the remainder being Zn and unavoidable impurities, is disclosed (for example, see Patent Document 1). In addition, as another solder material, a solder material in which, with respect to 100 mol % of all components, Sn accounts for 82 mol % to 94 mol %, Zn accounts for 5 mol % to 15 mol %, and Al accounts for 1 mol % to 3 mol % is disclosed. When converting the composition of this solder material into the weight ratio, Zn accounts for 2.84 wt % to 9.09 wt %, and Al accounts for 0.23 wt % to 0.75 wt %, the remainder being Sn (for example, see Patent Document 2).

### CITATION LIST

### PATENT DOCUMENT

Patent Document 1: Japanese Laid-Open Patent Publication No. 6-226489
Patent Document 2: Japanese Laid-Open Patent Publication No. 2002-1575

### SUMMARY OF THE INVENTION

### Problem to Be Solved by the Invention

The solder material according to Patent Document 1 needs the bonding temperature to be set to 350 °C to 410 °C. However, when a semiconductor element is bonded by reflow soldering at 350 °C or higher, the semiconductor element is softened and warp might occur. If warp occurs in the semiconductor element, great residual stress is left at a bonding part, resulting in decreasing bonding reliability. In addition, when an electrode film of a copper alloy, an insulating film of a polyimide, or the like is formed on the surface of the semiconductor element, the electrical characteristics of those films might change by being heated at 350 °C or higher. When the electrical characteristics of the electrode film, the insulating film, or the like change, the characteristics of the semiconductor device change. Meanwhile, the solder material according to Patent Document 2 has a bonding temperature of 250 °C to 255 °C. However, since the solder material has a melting point of approximately 200 °C, it is difficult to apply the solder material to the semiconductor device using a wide bandgap semiconductor element which reaches 180 °C or higher locally or momentarily during operation. Therefore, it is difficult for a conventional Zn-based solder material to enable bonding at 250 °C or lower and have a heat resistance of 180 °C or higher.

The present disclosure has been made to solve the above problem, and an object of the present disclosure is to provide a solder material which enables bonding at 250 °C or lower and has a heat resistance of 180 °C or higher.

### Means to Solve the Problem

A solder material according to the present disclosure contains Sn, Zn, and Al as main components, wherein the solder material has two endothermic peaks in differential scanning calorimetry, and a first alloy phase having an endothermic peak of 190 °C or higher and lower than 230 °C and a second alloy phase having an endothermic peak of 240 °C or higher and lower than 380 °C coexist.

### Effect of the Invention

A solder material according to the present disclosure has two endothermic peaks in differential scanning calorimetry, and a first alloy phase having an endothermic peak of 190 °C or higher and lower than 230 °C and a second alloy phase having an endothermic peak of 240 °C or higher and lower than 380 °C coexist. Thus, the solder material enables bonding at 250 °C or lower and can have a heat resistance of 180 °C or higher.

### BRIEF DESCRIPTION OF THE DRAWINGS

FIG. 1 is a flowchart showing a process for manufacturing a solder sheet according to embodiment 1.

FIG. 2 is a schematic view showing the process for manufacturing the solder sheet according to embodiment 1.

FIG. 3 is a schematic view showing the process for manufacturing the solder sheet according to embodiment 1.

FIG. 4 is a schematic view showing the process for manufacturing the solder sheet according to embodiment 1.

FIG. 5 is a cross-sectional schematic view of the solder material according to embodiment 1.

FIG. 6 shows a measurement result by differential scanning calorimetry of the solder material according to embodiment 1.

FIG. 7 is a flowchart showing a process for producing a semiconductor device according to embodiment 1.

FIG. 8 is a schematic view showing the process for producing the semiconductor device according to embodiment 1.

FIG. 9 is a schematic view showing the process for producing the semiconductor device according to embodiment 1.

FIG. 10 is a schematic view showing the process for producing the semiconductor device according to embodiment 1.

FIG. 11 is a schematic view showing the process for producing the semiconductor device according to embodiment 1.

FIG. 12 is a schematic view showing a die shear strength test in embodiment 1.

FIG. 13 is a table showing compositions and bonding strength test results of solder materials in embodiment 1.

### DESCRIPTION OF EMBODIMENTS

Hereinafter, a solder material, a method for producing a solder sheet, and a method for producing a semiconductor device according to embodiments for carrying out the present disclosure will be described in detail with reference to the drawings. In the drawings, the same reference characters denote the same or corresponding parts.

### Embodiment 1

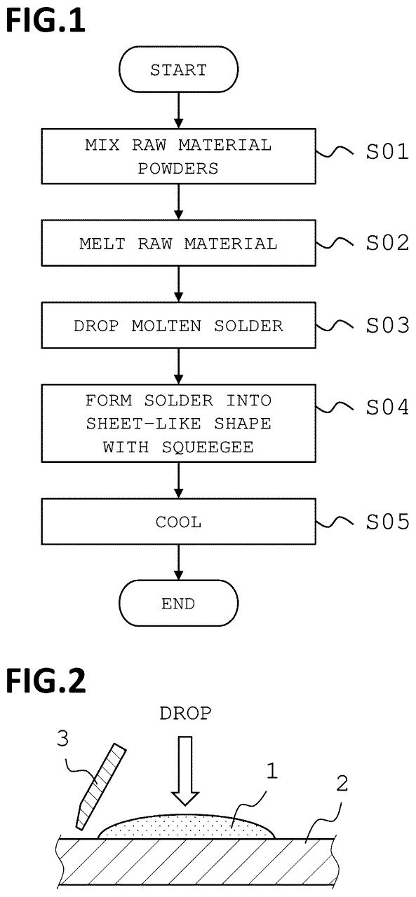

FIG. 1 is a flowchart showing a process for manufacturing a solder sheet according to embodiment 1. In step S01, raw material powders for a solder material are mixed. Specifically, 10 g of Zn powder, 5 g of Al powder, and 85 g of Sn powder are mixed. The average particle size of the raw material powders is preferably 10 μm to 100 μm. The average particle size of the raw material powders is an average particle size measured by using, for example, a laser diffraction particle size distribution meter.

Next, in step S02, the mixed raw material powders are melted by using a melting furnace to obtain a molten solder. The melting temperature is set to 700 °C. Regarding the melting temperature, as long as the melting temperature is equal to or higher than the melting point of Al, which has the highest melting point among Zn (melting point 420 °C), Al (melting point 660 °C), and Sn (melting point 232 °C) of the raw material powders, the powders can melt and are uniformly mixed. Next, in step S03, the molten solder is dropped on a flat-plate-shaped stage. Then in step S04, the molten solder dropped on the stage is formed into a sheet-like shape with a squeegee before the molten solder is solidified.

FIG. 2 is a schematic view showing the state where a molten solder 1 is dropped on a flat-plate-shaped stage 2 in step S03. The stage 2 is, for example, a flat stainless steel plate and has a temperature adjustment function. In step S03, the temperature of the stage 2 when the molten solder 1 is dropped thereon is set to approximately 300 °C As shown in FIG. 2, the thickness of the molten solder 1 when the molten solder 1 is dropped on the stage 2 is uneven.

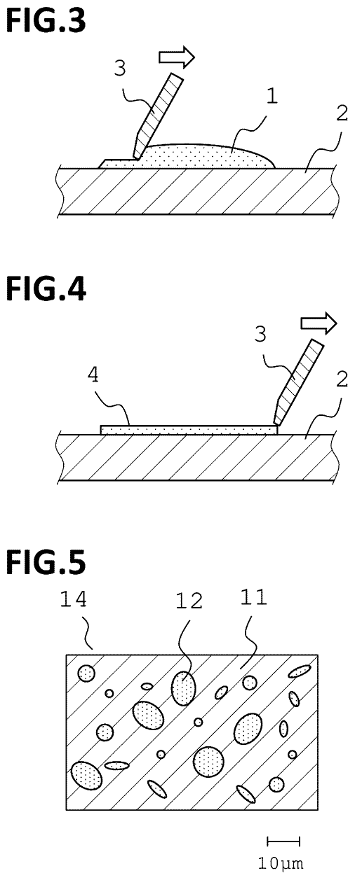

FIG. 3 and FIG. 4 are schematic views each showing the state where the molten solder 1 is formed into a sheet-like shape with a squeegee 3 in step S04. The interval between the squeegee 3 and the stage 2, which becomes the thickness of the solder sheet, is set to, for example, 100 μm. The squeegee 3 is moved in parallel to the surface of the stage 2. At this time, the interval between the squeegee 3 and the stage 2 is constantly kept uniform. As shown in FIG. 3 and FIG. 4, the squeegee 3 is moved before the molten solder 1 dropped on the stage 2 is solidified, and the molten solder 1 is formed into a sheet-like shape to manufacture a solder sheet 4.

Lastly, in step S05, the solder sheet 4 formed into a sheet-like shape is cooled. It is noted that the atmosphere from step S03 to step S05 may be an oxidizing atmosphere such as air, an inert atmosphere such as nitrogen or argon, or a reducing atmosphere such as formic acid or hydrogen. In a cooling step in step S05, the temperature of the stage 2 is adjusted to be cooled from 300 °C to 100 °C in the cooling time of longer than 20 seconds and 200 seconds or shorter. The cooling speed at this time is 1 °C/second or greater and less than 10 °C/second in absolute value.

The solder sheet 4 formed as above is cut into predetermined-size pieces. For example, the solder sheet 4 is cut into 5 mm-square pieces in accordance with the bonding surface of the semiconductor element. It is noted that the thickness of the solder sheet 4 is preferably 0.05 mm or greater and less than 1 mm. The thickness of the solder sheet 4 can be adjusted by using the interval between the squeegee 3 and the stage 2.

If a crack or the like occurs in the solder sheet, the solder sheet is returned to step S02, so that raw material loss can be reduced. It is noted that although the Zn powder, the Al powder, and the Sn powder are simultaneously mixed and melted from step S01 to step S02, another method may be adopted. For example, firstly, the Zn powder and the Sn powder may be mixed and melted to manufacture a bulk body of Sn and Zn. Then, the bulk body may be melted again and the Al powder may be added thereto. Although the molten solder is dropped and is formed into a sheet-like shape before the molten solder is solidified from step S03 to step S04, another method may be adopted. For example, the molten solder may be temporarily made into ball-shaped small solid bodies. Then, the ball-shaped small solid bodies may be dispersedly disposed on the stage. Lastly, the dispersedly disposed ball-shaped small solid bodies may be heated and compressed on the stage at 700 °C so as to be formed into a sheet-like shape. The solder sheet formed into a sheet-like shape by heating and compression at 700 °C is cooled from 300 °C to 100 °C in the cooling time of longer than 20 seconds and 200 seconds or shorter. The cooling speed at this time is 1 °C/second or greater and less than 10 °C/second in absolute value.

FIG. 5 is a cross-sectional schematic view of a solder material forming the solder sheet according to the present embodiment. FIG. 5 schematically illustrates a composition when a cross section of the solder material is magnified and observed with a scanning electron microscope. As shown in FIG. 5, the solder material 14 forming the solder sheet 4 of the present embodiment is separated into two phases. A second alloy phase 12 is dispersed in a first alloy phase 11 in the solder material 14. When a cross section of the second alloy phase 12 is approximated by circle, the diameter thereof is 20 μm or less.

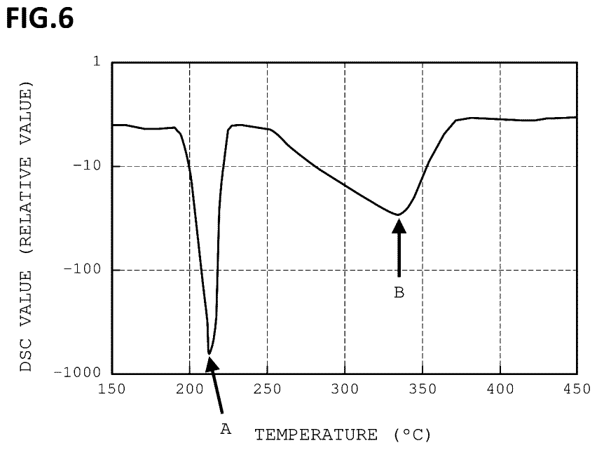

FIG. 6 shows a measurement result by differential scanning calorimetry of the solder material according to the present embodiment. The differential scanning calorimetry (hereinafter referred to as DSC) is a method for measuring a temperature difference between a reference substance and a measurement target substance while applying a fixed level of heat to measure endothermic reaction, exothermic reaction, or the like of the measurement target substance from the temperature difference. In FIG. 6, the horizontal axis indicates the temperature and the vertical axis indicates the calorie (hereinafter referred to as a DSC value) calculated from the temperature difference between the reference substance and the measurement target substance. It is noted that the vertical axis is indicated by logarithms. In a DSC curve shown in FIG. 6, the direction in which the DSC value decreases indicates the endothermic reaction, and the direction in which the DSC value increases indicates the exothermic reaction. As shown in FIG. 6, in the solder material according to the present embodiment, two endothermic peaks are observed in the DSC curve. The two endothermic peaks are an endothermic peak A appearing at approximately 210 °C and an endothermic peak B appearing at approximately 340 °C.

It is found from composition analysis and detailed DSC measurement that the first alloy phase and the second alloy phase shown in FIG. 5 and the two endothermic peaks shown in FIG. 6 have the following relationship. The endothermic reaction in the first alloy phase 11 corresponds to the endothermic peak A and the endothermic reaction in the second alloy phase 12 corresponds to the endothermic peak B. In addition, the first alloy phase 11 is a phase that contains Sn as a main component, and contains Al and Zn, and the second alloy phase 12 is a phase that contains Zn as a main component, and contains Al and Sn.

Next, the specific heat capacities of the first alloy phase and the second alloy phase are compared. The specific heat capacities of the first alloy phase and the second alloy phase are measured in conformity with Japanese Industrial Standards JIS K 7123 which allows calculation of the specific heat capacity by using DSC. As a result, it is found that the specific heat capacity of the first alloy phase is greater than the specific heat capacity of the second alloy phase. The specific heat capacity corresponds to a calorie required for increasing the temperature of a unit mass of substance by unit temperature, and the unit thereof is J/(kg·K).

In general, when manufacturing a solder material such as the SAC305, which is an alloy of Sn, Ag, and Cu, the solder material is quenched so as not to cause phase separation. Specifically, the absolute value of the cooling speed of a molten solder material is, for example, 50 °C/second or greater. In the manufacturing method for the solder material according to the present embodiment, the absolute value of the cooling speed from 300 °C to 100 °C is set to 1 °C/second or greater and less than 10 °C/second, and thus, as shown in FIG. 5, the solder material having two separated phases of the first alloy phase and the second alloy phase is obtained.

Next, a method for producing a semiconductor device according to the present embodiment will be described.

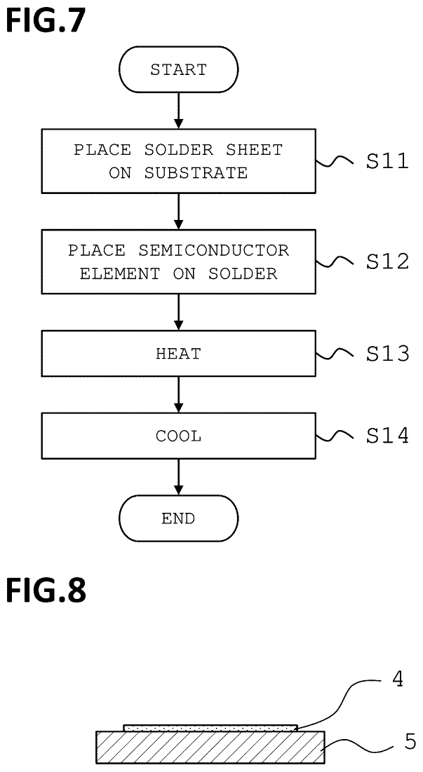

FIG. 7 is a flowchart showing a process for producing a semiconductor device according to the present embodiment. In step S11, a solder sheet 4 is placed on a substrate 5 which is a bonding target member. FIG. 8 is a schematic view showing the state where the solder sheet 4 is placed on the substrate 5 in step S11. The substrate 5 is, for example, a copper plate such as tough pitch copper having a thickness of 1 mm and a size of 10 mm square. The solder sheet 4 has, for example, a thickness of 100 μm and a size of 5 mm square.

It is noted that the outermost surface of the substrate 5 is formed from pure copper and is not subjected to a plating treatment. However, an anti-corrosive agent having a decomposition temperature of 100 °C or lower may be applied to the outermost surface of the substrate 5 in a range of not affecting solder bonding. In addition, an adhesive that is thermally decomposed at 100 °C or higher may be applied to the surface of the substrate 5 in order to prevent the solder sheet 4 from being displaced at the time of placing the solder sheet 4. The viscosity of the adhesive is preferably 200 Pa·s or greater. Alternatively, a resist film may be applied in a region other than the bonding surface of the surface of the substrate 5 in order to prevent the solder sheet 4 from being displaced at the time of placing the solder sheet 4.

The solder sheet 4 may be more or less curved. This is because the solder sheet 4 melts by heat and thus the initial shape does not have much effect. However, if the solder sheet 4 is so curved that the position of the semiconductor element might be displaced at the time of placing a semiconductor element in the next step, the curve of the solder sheet 4 needs to be corrected.

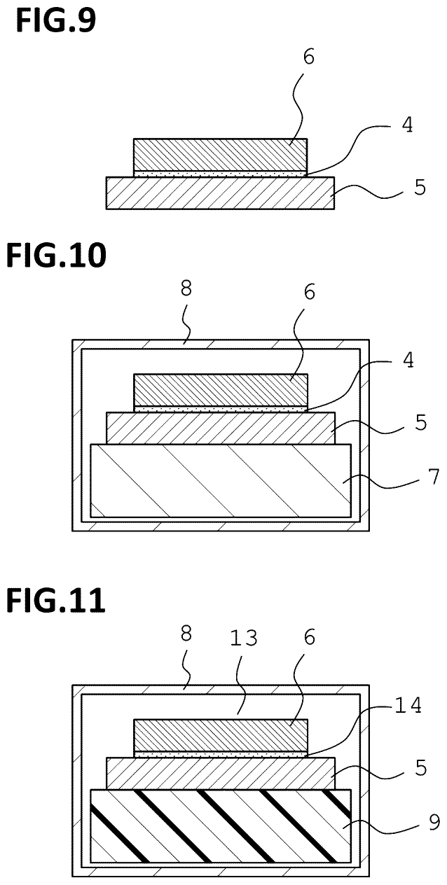

Next, in step S12, a semiconductor element 6 is placed on the solder sheet 4. FIG. 9 is a schematic view showing the state where the semiconductor element 6 is placed on the solder sheet 4 in step S12. The semiconductor element 6 is, for example, a semiconductor element made of SiC and has a thickness of 100 μm and a size of 5 mm square. A Ni film may be formed on the bonding target surface of the semiconductor element 6 that faces the solder sheet 4 in order to improve the wettability with the solder material. In addition, an adhesive may be applied to a bonding target surface of one of the semiconductor element 6 and the solder sheet 4 in order to prevent the semiconductor element 6 from being displaced at the time of placing the semiconductor element 6.

Next, as shown in FIG. 10, an object in which the substrate 5, the solder sheet 4, and the semiconductor element 6 are placed in this order is placed on a hot plate 7, and is disposed inside a closed furnace 8. The inside of the closed furnace 8 is adjusted to an atmosphere that can reduce an oxide film and contains 3 vol % of hydrogen, the remainder being nitrogen. In step S13, the solder sheet 4 is heated and melted through heating by using the hot plate 7 at 250 °C for 10 minutes. Accordingly, the substrate 5 and the semiconductor element 6 are bonded by the solder material 14. Note that, although not illustrated, it is preferable to apply pressure from above the semiconductor element 6 in order to strengthen the bonding between the substrate 5 and the semiconductor element 6 by the solder material 14.

Next, as shown in FIG. 11, the semiconductor device 13 in which the substrate 5 and the semiconductor element 6 are bonded by the solder material 14 is transferred onto a cooling stage 9 in the closed furnace 8. The inside of the closed furnace 8 is adjusted to an atmosphere that can reduce an oxide film and contains 3 vol % of hydrogen, the remainder being nitrogen. In step S14, the solder material 14 is cooled from 250 °C to 100 °C for 500 seconds by using the cooling stage 9. The absolute value of the cooling speed at this time is 0.3 °C/second. Such a slow cooling speed is not adopted in a process for producing a general semiconductor device. This is because tact time increases. In the present embodiment, by adopting the cooling speed of 0.3 °C/second (absolute value), it is possible to inhibit the occurrence of warp, waviness, or the like of the semiconductor element 6 due to thermal contraction of the solder material 14. It is noted that although the semiconductor device 13 is transferred from the hot plate 7 onto the cooling stage 9 when proceeding from step S13 to step S14, a temperature adjustment stage that has both functions of the hot plate and the cooling stage may be used. This temperature adjustment stage can adjust the temperature of a substance on the stage in a temperature range of, for example, 20 °C to 400 °C. Using such a temperature adjustment stage eliminates a step of transferring the semiconductor device 13 from the hot plate 7 onto the cooling stage 9.

It is noted that, in a cooling step in step S14, the cooling time from 250 °C to 100 °C is preferably 300 seconds or longer. That is, the cooling speed from 250 °C to 100 °C is preferably 0.5 °C/second or less in absolute value. If the cooling time from 250 °C to 100 °C is 300 seconds or longer, the occurrence of warp, waviness, or the like of the semiconductor element 6 due to thermal contraction of the solder material 14 can be inhibited.

In the semiconductor device 13 produced by such a method as above, the solder material 14 which bonds the substrate 5 and the semiconductor element 6 enables bonding at 250 °C or lower and has a heat resistance of 180 °C or higher. Hereinafter, the reasons therefor will be described.

As shown in FIG. 6, the solder material according to the present embodiment has two alloy phases of the first alloy phase corresponding to the endothermic peak A appearing at approximately 210 °C and the second alloy phase corresponding to the endothermic peak B appearing at approximately 340 °C. In a heating step at 250 °C in step S13 in the process for producing the semiconductor device, the first alloy phase having an endothermic peak at approximately 210 °C melts and thus can bond the substrate and the semiconductor element. Meanwhile, when the semiconductor device has reached 180 °C or higher, the first alloy phase having an endothermic peak at approximately 210 °C is softened, but the second alloy phase having an endothermic peak at approximately 340 °C is not softened. As a result, the semiconductor device according to the present embodiment is not unnecessarily softened even at 180 °C or higher, thus exhibiting a heat resistance of 180 °C or higher.

In the above description of the present embodiment, the composition of the solder material has such a weight ratio that Zn accounts for 10 wt %, Al accounts for 5 wt %, and Sn accounts for 85 wt %. Hereinafter, the characteristics of solder materials having different compositional ratios will be described. It is noted that the solder material according to the present embodiment may include unavoidable impurities, other than main components.

In step S01 of the flowchart of the process for manufacturing the solder sheet shown in FIG. 1, a plurality of kinds of solder sheets were manufactured by changing the mixing ratio of the Zn powder, the Al powder, and the Sn powder when mixing the raw material powders for the solder material. By using those solder sheets, a plurality of semiconductor devices having different solder material compositions were produced, on the basis of the flowchart of a process for producing a semiconductor device shown in FIG. 7. A die shear strength test was carried out on the plurality of semiconductor devices manufactured as above.

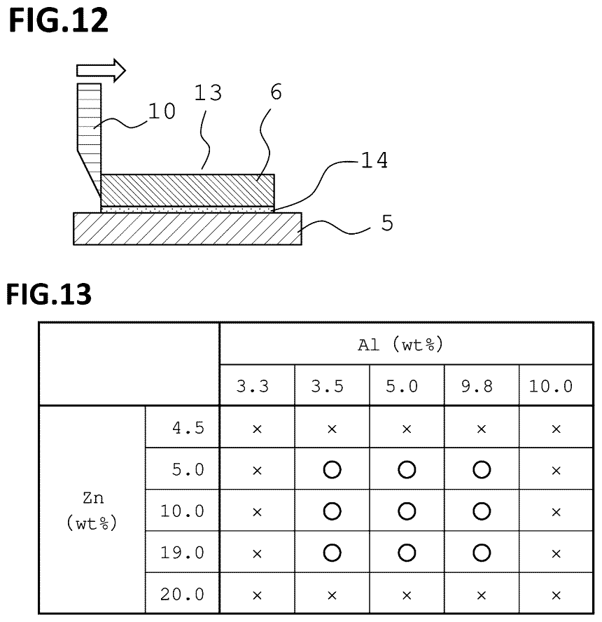

FIG. 12 is a schematic view showing the die shear strength test in the present embodiment. As shown in FIG. 12, with respect to the semiconductor device 13 in which the substrate 5 and the semiconductor element 6 were bonded by the solder material 14, a die 10 was brought into contact with a side surface of the semiconductor element 6, and a load was applied to the die 10 in a direction parallel to a bonding surface. The load applied to the die 10 was gradually increased. The value of the load at which the semiconductor element 6 could not withstand the load from the die 10 and moved in a lateral direction, is defined as the bonding strength of the bonding surface. It is noted that the bonding strength of the semiconductor device 13 was measured at 20 °C.

FIG. 13 is a table showing the compositions of the solder materials and test results of the bonding strength in the present embodiment. In the table shown in FIG. 13, the column indicates the weight percentage of Zn of the solder material and the row indicates the weight percentage of Al of the solder material. The weight percentage of Sn of the solder material is a value obtained by subtracting the weight percentage of Zn and the weight percentage of Al from 100 wt %. In FIG. 13, the marks “o” and “x” show the evaluation results of the bonding strength. With the lowest bonding strength set to 40 MPa, a case where the bonding strength at 20 °C is 40 MPa or greater is defined as “o”, and a case where the bonding strength at 20 °C is less than 40 MPa is defined as “x”. The reason for setting the lowest bonding strength to 40 MPa is because the bonding strength at 20 °C of the SAC305, which is a general solder material, is approximately 40 MPa.

As shown in the table in FIG. 13, the solder materials in which, with respect to the total of 100 wt %, Zn accounted for 5 wt % or greater and less than 20 wt % and Al accounted for 3.5 wt % or greater and less than 10 wt %, exhibited the characteristic that a bonding strength at 20 °C was 40 MPa or greater.

In a solder material having less than 5 wt % of Zn, the ratio of Sn occupied in the solder material becomes high, and thus the strength of the solder material itself becomes low. Accordingly, the solder material having less than 5 wt % of Zn had a bonding strength of less than 40 MPa at 20 °C Meanwhile, in a solder material having 20 wt % or greater of Zn, the strength of the solder material itself becomes high, but the ratio of Sn occupied in the solder material becomes low. Accordingly, the solder material does not completely melt at the bonding temperature of 250 °C, thus reducing the initial bonding strength. As a result, the bonding strength at 20 °C became less than 40 MPa. In addition, it is considered that, since the increase of the ratio of Zn causes the solder material to be susceptible to oxidization, the initial bonding strength was reduced due to the oxidization.

Also, in a solder material having less than 3.5 wt % of Al, the ratio of Sn occupied in the solder material becomes high, and thus the strength of the solder material itself becomes low. Accordingly, the solder material having less than 3.5 wt % of Al had a bonding strength of less than 40 MPa at 20°C. Meanwhile, in a solder material having not less than 10 wt % of Al, the strength of the solder material itself becomes high, but the ratio of Sn occupied in the solder material becomes low. Accordingly, the solder material does not completely melt at the bonding temperature of 250 °C, thus reducing the initial bonding strength. As a result, the bonding strength became less than 40 MPa. Note that it is possible to improve the bonding strength by setting the bonding temperature to 250 °C or higher if the ratio of Al is high. However, setting the bonding temperature to 250 °C or higher might cause the occurrence of warp in the semiconductor element, and thus is not preferable.

From the results described above, it is found that the solder material in which, with respect to the total of 100 wt %, Zn accounts for 5 wt % or greater and less than 20 wt %, and Al accounts for 3.5 wt % or greater and less than 10 wt %, the remainder being Sn, enables bonding at 250 °C or lower and has a heat resistance of 180 °C or higher.

Next, DSC measurement was carried out on the solder materials for which “o” is indicated as evaluations shown in the table of FIG. 13. As a result, two endothermic peaks as shown in FIG. 6 are observed in all of the solder materials. At this time, the peak temperatures of the endothermic peak A on the lower temperature side were in a range of 190 °C or higher and less than 230 °C. In addition, the peak temperatures of the endothermic peak B on the higher temperature side were in a range of 240 °C or higher and less than 380 °C. Consequently, it is found that the solder material which has two endothermic peaks in DSC measurement and in which the first alloy phase having an endothermic peak in a range of 190 °C or higher and lower than 230 °C and the second alloy phase having an endothermic peak in a range of 240 °C or higher and lower than 380 °C coexist, enables bonding at 250 °C or lower and has a heat resistance of 180 °C or higher.

Regarding a solder material having 20 wt % or greater of Zn, the height of the endothermic peak on the low temperature side decreases. The peak temperatures of the two endothermic peaks are shifted to the high temperature side as the ratio of Al increases. Consequently, it is estimated that the solder material is less likely to melt at the bonding temperature of 250 °C when Al accounts for 10 wt % or greater.

It is noted that, in the process for producing the semiconductor device according to the present embodiment, the atmosphere at the times of bonding and cooling is set to 3 vol % of hydrogen, the remainder being nitrogen, but may be set to 100 vol % of hydrogen if there is no safety problem. In addition, the atmosphere may be set to be an atmosphere of an organic acid such as formic acid, other than hydrogen. As the organic acid, it is possible to use formic acid, acetic acid, lauric acid, caprylic acid, pelargonic acid, heptylic acid, caproic acid, and the like. Furthermore, before being put into the process for producing the semiconductor device, the solder sheet may be immersed in the organic acid to form a coating of an organic acid salt on the surface of the solder sheet.

Although the disclosure is described above in terms of an exemplary embodiment, it should be understood that the various features, aspects, and functionality described in the embodiment are not limited in their applicability to the particular embodiment with which they are described, but instead can be applied alone or in various combinations to the embodiment of the disclosure.

It is therefore understood that numerous modifications which have not been exemplified can be devised without departing from the scope of the present disclosure. For example, at least one of the constituent components may be modified, added, or eliminated.

### DESCRIPTION OF THE REFERENCE CHARACTERS

1 molten solder
2 stage
3 squeegee
4 solder sheet
5 substrate
6 semiconductor element
7 hot plate
8 closed furnace
9 cooling stage
10 die
11 first alloy phase
12 second alloy phase
13 semiconductor device
14 solder material

1. A solder material containing Sn, Zn, and Al, as main components, wherein,
with respect to a total of 100 wt %, Zn accounts for 5 wt % or greater and less than 20 wt %, and Al accounts for 3.5 wt % or greater and less than 10 wt %, a remainder being Sn,
the solder material has two endothermic peaks in differential scanning calorimetry, and
a first alloy phase having an endothermic peak in a range of 190 °C or higher and lower than 230 °C and a second alloy phase having an endothermic peak in a range of 240 °C or higher and lower than 380 °C coexist.

2. The solder material containing Sn, Zn, and Al, as main components, wherein, regarding a specific heat capacity calculated by the differential scanning calorimetry, the specific heat capacity of the first alloy phase is greater than the specific heat capacity of the second alloy phase.

3. The solder material according to claim 1, wherein, regarding a specific heat capacity calculated by the differential scanning calorimetry, the specific heat capacity of the first alloy phase is greater than the specific heat capacity of the second alloy phase.

4. A method for producing a semiconductor device, the method comprising:
a step of disposing, on a surface of a bonding target member, a solder sheet formed from the solder material according to claim 1;
a step of disposing a semiconductor element on a surface of the solder sheet;
a step of heating and melting the solder sheet while applying pressure between the bonding target member and the semiconductor element; and
a cooling step of cooling the bonding target member, the solder material, and the semiconductor element.

5. The method for producing the semiconductor device according to claim 4, wherein an absolute value of a cooling speed from 250 °C to 100 °C in the cooling step is 0.5 °C/second or less.

6. A method for producing a solder sheet, the method comprising:
a heating and melting step of heating and melting a solder material in which, with respect to a total of 100 wt %, Zn accounts for 5 wt % or greater and less than 20 wt %, and Al accounts for 3.5 wt % or greater and less than 10 wt %, a remainder being Sn;
a forming step of dropping the molten solder material on a surface of a flat-plate-shaped substrate, and spreading the solder material on the surface of the substrate in a state where the solder material has melted, so as to form the solder material into a sheet-like shape; and
a cooling step of cooling the solder material formed into the sheet-like shape, wherein
an absolute value of a cooling speed from 300 °C to 100 °C in the cooling step is 1 °C/second or greater and less than 10 °C/second.

7. A method for producing a semiconductor device, the method comprising:
a step of disposing, on a surface of a bonding target member, a solder sheet formed from the solder material according to claim 2;
a step of disposing a semiconductor element on a surface of the solder sheet;
a step of heating and melting the solder sheet while applying pressure between the bonding target member and the semiconductor element; and
a cooling step of cooling the bonding target member, the solder material, and the semiconductor element.

8. The method for producing the semiconductor device according to claim 7, wherein an absolute value of a cooling speed from 250 °C to 100 °C in the cooling step is 0.5 °C/second or less.

9. A method for producing a semiconductor device, the method comprising:
a step of disposing, on a surface of a bonding target member, a solder sheet formed from the solder material according to claim 3;
a step of disposing a semiconductor element on a surface of the solder sheet;
a step of heating and melting the solder sheet while applying pressure between the bonding target member and the semiconductor element; and
a cooling step of cooling the bonding target member, the solder material, and the semiconductor element.

10. The method for producing the semiconductor device according to claim 9, wherein an absolute value of a cooling speed from 250 °C to 100 °C in the cooling step is 0.5 °C/second or less.
